(19) United States
(12) Patent Application Publication
(10) Pub. No.: US 2020/0161555 A1
(43) Pub. Date: May 21, 2020

(54) ORGANIC LIGHT-EMITTING DIODE DISPLAY SUBSTRATE, METHOD FOR FABRICATING THE SAME, ORGANIC LIGHT-EMITTING DIODE DISPLAY PANEL, AND DISPLAY DEVICE

(71) Applicants: Chengdu BOE Optoelectronics Technology Co., Ltd., Chengdu (CN); BOE Technology Group Co., Ltd., Beijing (CN)

(72) Inventors: Fuqiang TANG, Beijing (CN); Tongjin PARK, Beijing (CN); Chengguo AN, Beijing (CN); Jinxing XU, Beijing (CN)

(73) Assignees: Chengdu BOE Optoelectronics Technology Co., Ltd.; BOE Technology Group Co., Ltd.

(21) Appl. No.: 16/520,814

(22) Filed: Jul. 24, 2019

(30) Foreign Application Priority Data
Nov. 20, 2018 (CN) 201811382009.8

(51) Int. Cl. H01L 51/00; H01L 51/52

(52) U.S. Cl. CPC H01L 51/0023; H01L 51/5225; H01L 51/5234; H01L 2251/5338; H01L 2251/5315; H01L 51/0097

(57) ABSTRACT

The disclosure discloses an organic light-emitting diode display substrate, a method for fabricating the same, an organic light-emitting diode display panel, and a display device. Since display brightness is required of a top-emitting organic light-emitting diode element with a large size, the resistance of a cathode should not be too large, so the cathode should be made with a large thickness, but if the thickness of the cathode is too large, then a light exit ratio of the element may be degraded. Accordingly in the embodiments of the disclosure, cathodes can be formed in a grid structure to thereby guarantee a high light exit ratio while guaranteeing display brightness thereof; and the cathodes are made of a metal nanometer material.

### CROSS-REFERENCE TO RELATED APPLICATION

This application claims the priority of Chinese Patent Application No. 201811382009.8, filed with the Chinese Patent Office on Nov. 20, 2018, the content of which is hereby incorporated by reference in its entirety.

### FIELD

The present disclosure relates to the field of display technologies, and particularly to an organic light-emitting diode display substrate, a method for fabricating the same, an organic light-emitting diode display panel, and a display device.

### BACKGROUND

Of flat panel display panels, an Organic Light-Emitting Diode (OLED) display panel has been widely favored due to its advantages of self-emission, a high response speed, a wide angle of view, high brightness, high saturation, a low weight, a small thickness, etc.

### SUMMARY

Embodiments of the disclosure provide an organic light-emitting diode display substrate, a method for fabricating the same, an organic light-emitting diode display panel, and a display device.

In one aspect, an embodiment of the disclosure provides a method for fabricating an organic light-emitting diode display substrate, the method including:
forming an integral cathode layer of a metal nanometer material on a base substrate;
thermally curing a part of the cathode layer, wherein the cured part of the cathode layer is patterned in a grid structure; and
removing a pattern of the remaining cathode layer which is not cured, to form cathodes in the grid structure.

Optionally, in the method above according to the embodiment of the disclosure, the forming the integral cathode layer of the metal nanometer material on the base substrate includes:
coating the metal nanometer material on the base substrate through physical vapor deposition, inkjet printing, or high-temperature evaporation and plating to form the integral cathode layer.

Optionally, in the method above according to the embodiment of the disclosure, the thermally curing a part of the cathode layer includes:
curing a part of the cathode layer through laser sintering.

Optionally, in the method above according to the embodiment of the disclosure, the removing the pattern of the remaining cathode layer which is not cured, to form the cathodes in the grid structure includes:
dissolving and removing the pattern of the remaining cathode layer which is not cured, with an organic solvent to form the cathodes in the grid structure.

Optionally, in the method above according to the embodiment of the disclosure, orthographic projections of the cathodes onto the base substrate overlap with opening areas of the base substrate.

Optionally, in the method above according to the embodiment of the disclosure, a wavelength of laser in laser sintering ranges from 400 nm to 700 nm, a power of the laser ranges from 1000 W/cm² to 3000 W/cm², and an energy of the laser ranges from 0.29 J/cm² to 0.85J/cm².

Optionally, in the method above according to the embodiment of the disclosure, the cathode layer is irradiated with laser in laser sintering for one to three seconds.

Optionally, in the method above according to the embodiment of the disclosure, the organic solvent includes at least one of ethyl acetate, acetone, or synthetic acid.

Optionally, in the method above according to the embodiment of the disclosure, a melting temperature of the metal nanometer material is below 150° C.

In another aspect, an embodiment of the disclosure further provides an organic light-emitting diode display substrate including a base substrate, and anodes, organic functional layers, and cathodes stacked over the base substrate, wherein the cathodes are in a grid structure, and the cathodes are made of a metal nanometer material.

Optionally, in the organic light-emitting diode display substrate above according to the embodiment of the disclosure, the base substrate includes a plurality of opening areas, and orthographic projections of the cathodes onto the base substrate overlap with the plurality of opening areas.

Optionally, in the organic light-emitting diode display substrate above according to the embodiment of the disclosure, the base substrate is a flexible base substrate.

In still another aspect, an embodiment of the disclosure further provides an organic light-emitting diode display panel including the organic light-emitting diode display substrate in any one of the solutions above according to the embodiment of the disclosure.

In yet another aspect, an embodiment of the disclosure further provides a display device including the organic light-emitting diode display panel above according to the embodiment of the disclosure.

### BRIEF DESCRIPTION OF THE DRAWINGS

In order to more clearly illustrate the technical solutions in the embodiments of the present disclosure, the drawings will be briefly described in the description of the embodiments as following, and the drawings in the following description are only some of the embodiments of the present disclosure, and it is obvious for those skilled in the art that other drawings can be obtained from these drawings without paying any creative work.

FIG. 1 is a flow chart of a method for fabricating an organic light-emitting diode display substrate according to the embodiments of the disclosure.

FIG. 2A is a schematic diagram of curing a metal nanometer material below 120 □ according to the embodiments of the disclosure.

FIG. 2B is a schematic diagram of an organic light-emitting diode display substrate in a grid structure according to the embodiments of the disclosure in a top view.

FIG. 3 is a schematic structural diagram of an organic light-emitting diode display substrate according to the embodiments of the disclosure.

FIG. 4 is a schematic structural diagram of the organic light-emitting diode display substrate according to the embodiments of the disclosure in a top view.

FIG. 5A to FIG. 5C are schematic diagrams of respective steps in a method for fabricating the organic light-emitting diode display substrate as illustrated in FIG. 3 according to the embodiments of the disclosure.

FIG. 6 is a schematic structural diagram of a display device according to the embodiments of the disclosure.

### DETAILED DESCRIPTION OF THE EMBODIMENTS

Since it is difficult to bottom-emitting OLED elements in an OLED screen with a large size and a high resolution form due to an opening ratio, more and more manufacturers come to form top-emitting OLED elements in the OLED screen. It is highly desirable for those skilled in the art to form a top-emitting OLED element with a high light exit ratio while guaranteeing the brightness thereof.

In order to make the objects, technical solutions, and advantages of the disclosure more apparent, particular implementations of an organic light-emitting diode display substrate, a method for fabricating the same, an organic light-emitting diode display panel, and a display device according to the embodiments of the disclosure will be described below in details with reference to the drawings. It shall be appreciated that the preferable embodiments to be described below are only intended to illustrate and explain the disclosure, but not to limit the disclosure thereto. The embodiments of the disclosure and the features in the embodiments can be combined with each other unless they conflict with each other.

The thicknesses, sizes and shapes of respective layers in the drawings are not intended to reflect any real proportion of the organic light-emitting diode display substrate, but only intended to illustrate the content of the disclosure.

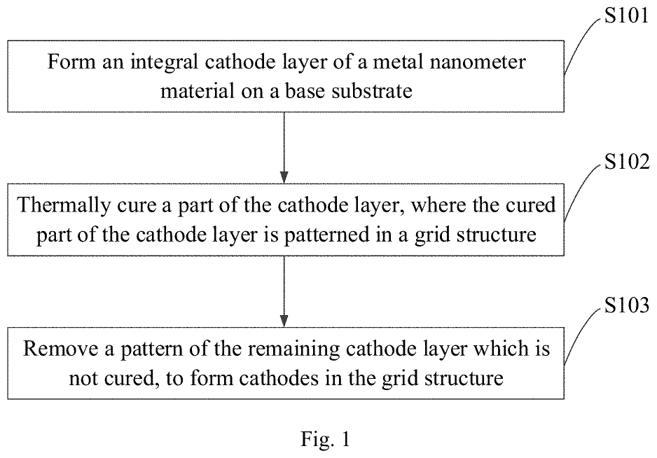

As illustrated in FIG. 1, a method for fabricating an organic light-emitting diode display substrate according to the embodiments of the disclosure includes the following steps.

Step S101 is to form an integral cathode layer of a metal nanometer material on a base substrate.

Step S102 is to thermally cure a part of the cathode layer, where the cured part of the cathode layer is patterned in a grid structure; and

Step S103 is to remove a pattern of the remaining cathode layer which is not cured, to form cathodes in the grid structure.

In the method for fabricating an organic light-emitting diode display substrate, since high display brightness is required of a top-emitting OLED element with a large size, the resistance of a cathode shall not be too large, so the cathode should be made with a large thickness, but if the thickness of the cathode is too large, then a light exit ratio of the element may be degraded. Accordingly in the embodiments of the disclosure, the cathodes can be formed in the grid structure in the method above to thereby guarantee a high light exit ratio while guaranteeing the display brightness thereof; and the cathodes are made of the metal nanometer material, and since the metal nanometer material can be thermally cured at a lower temperature, an organic layer will not be destroyed. A flexible OLED display panel with a large size can be fabricated using the cathodes in the grid structure.

Optionally, in the method above according to the embodiments of the disclosure, forming the integral cathode layer of the metal nanometer material on the base substrate particularly can include: coating the metal nanometer material on the base substrate through physical vapor deposition, inkjet printing, or high-temperature evaporation and plating to form the integral cathode layer. Of course, optionally, the metal nanometer material can be coated otherwise on the base substrate, as long as the metal nanometer material can be spin-coated on the base substrate without departing from the claimed scope of the disclosure.

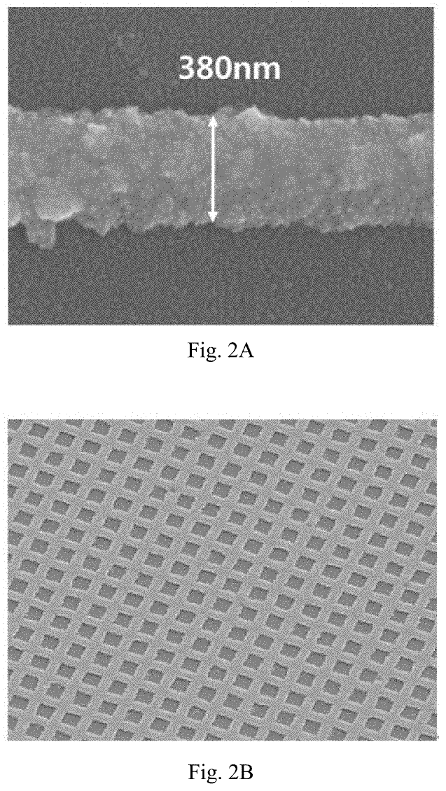

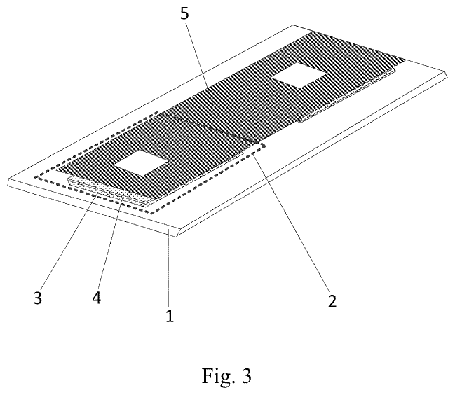

A cathode is generally made of a block of metal material in the related art, and the block of metal material should be melted at a temperature above 1000 □; and in the embodiments of the disclosure, the cathode is made of the metal nanometer material which can be melted at a temperature below 150 □, so the metal nanometer material can absorb specific laser while being irradiated with the laser, and thus can be cured. Since a light-emitting layer in an OLED element is susceptible to high temperature so that the performance thereof is degraded, the metal nanometer material can be cured at a lower temperature so that the performance of the light-emitting layer will not be degraded in the embodiments of the disclosure. Optionally, in the method above according to the embodiments of the disclosure, thermally curing a part of the cathode layer particularly can include: curing a part of the cathode layer through laser sintering, where the metal nanometer material (e.g., a silver nanometer material, a magnesium nanometer material, etc.) can be sintered locally using a high-precision Femto Second (FS) laser to form the pattern in the grid structure. In some embodiments, as illustrated in FIG. 2A and FIG. 2B, FIG. 2A is a schematic diagram of the metal nanometer material cured at a temperature below 120 □, where the cured part is a part with the width of 380 nm as illustrated in FIG. 2A, and FIG. 2B is a schematic diagram of the formed cathode in the grid structure.

Optionally, in the method above according to the embodiments of the disclosure, removing the pattern of the remaining cathode layer which is not cured, to form the cathodes in the grid structure particularly includes: dissolving and removing the pattern of the remaining cathode layer which is not cured, with an organic solvent to form the cathodes in the grid structure. In some embodiments, the organic solvent includes but will not be limited to at least one of ethyl acetate, acetone, or synthetic acid.

Optionally, in order to enable the elements to emit light, in the method above according to the embodiments of the disclosure, orthographic projections of the cathodes onto the base substrate overlap with opening areas.

Optionally, in the method above according to the embodiments of the disclosure, the FS laser emits laser for an extremely short period of time, e.g., only several femto seconds, so that the laser is the shortest pulse available at present under an experimental condition; instantaneous power of the FS laser is so high that it can be up to hundreds of trillions of watts, which is more than a hundred of times of total power of electricity generated all over the world; and the laser of the FT laser can be focused into a spatial area with a shorter diameter than our hair, so the intensity of an electromagnetic field is several times of an acting force of an atomic nucleus to electrons around it, and a number of extreme physical conditions are unavailable on the earth, even with the aid of other solutions. Since there is ultra-high peak power of the FS laser, the intensity of the laser can be up to an order of 1022 W/cm² after being focused. Accordingly the wavelength of the laser in laser sintering according to the embodiments of the disclosure can range from 400 nm to 700 nm, the power of the laser can range from 1000 W/cm² to 3000 W/cm², and the energy of the laser can range from 0.29 J/cm² to 0.85 J/cm², so that the metal nanometer material can be well cured. Of course, optionally, these parameters, such as the wavelength, the power, the energy, of the laser can be adjusted flexibly under a real process condition.

Optionally, in the method above according to the embodiments of the disclosure, the metal nanometer material can be irradiated with the laser in laser sintering for one to three seconds. Of course, optionally, the time the metal nanometer material is irradiated with the laser can be adjusted flexibly under a real process condition.

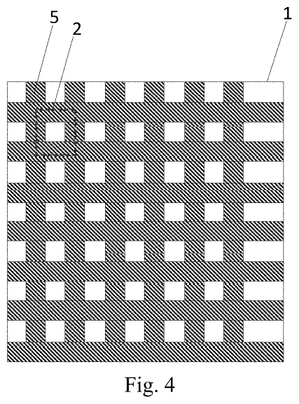

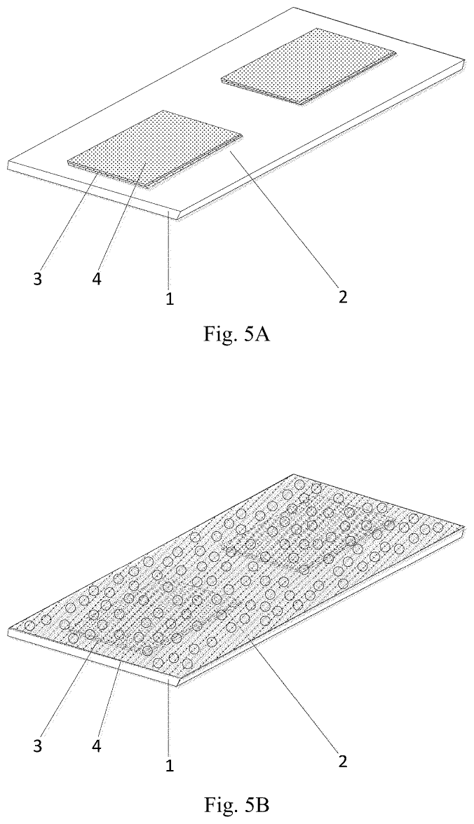

Based upon the same inventive idea, the embodiments of the disclosure further provide an organic light-emitting diode display substrate as illustrated in FIG. 3 and FIG. 4, where FIG. 3 is a schematic structural diagram of the display substrate, and FIG. 4 is a schematic structural diagram of the display substrate in a top view. The organic light-emitting diode display substrate includes a base substrate 1, and anodes 3, organic functional layers 4, and cathodes 5 stacked over the base substrate 1 in that order, where the cathodes 5 are in a grid structure, and the cathodes 5 are made of the metal nanometer material.

In the organic light-emitting diode display substrate according to the embodiments of the disclosure, the cathodes are formed in the grid structure so that there will be a high light exit ratio while guaranteeing display brightness; and the cathodes are made of the metal nanometer material, and since the metal nanometer material can be thermally cured at a lower temperature, an organic functional layer will not be destroyed. A flexible OLED display panel with a large size can be fabricated using the cathodes in the grid structure.

Optionally, the organic light-emitting diode display substrate according to the embodiments of the disclosure further includes other functional layers which are the same as in the related art, so a repeated description thereof will be omitted here.

Optionally, in order to enable OLED elements to emit light, in the organic light-emitting diode display substrate above according to the embodiments of the disclosure, as illustrated in FIG. 3, the base substrate 1 includes a plurality of opening areas 2, and orthographic projections of the cathodes 5 onto the base substrate 1 overlap with the plurality of opening areas 2. FIG. 3 illustrates a schematic structural diagram of only two opening areas 2 corresponding to the cathodes 5 in the grid structure, where the thicknesses of the cathodes 5 in the grid structure can be made to provide a high light exit ratio while guaranteeing display brightness.

Optionally, in the organic light-emitting diode display substrate above according to the embodiments of the disclosure, as illustrated in FIG. 3, the base substrate 1 can be a flexible base substrate, and since the cathodes 5 in the grid structure can be bent easily, a flexible OLED display panel with a large size can be fabricated using the cathodes 5.

A method for fabricating a display panel according to the embodiments of the disclosure will be described below in details taking the structure of the organic light-emitting diode display panel as illustrated in FIG. 3 as an example.

Steps in the method for fabricating a display panel as illustrated in FIG. 3 are as follows.

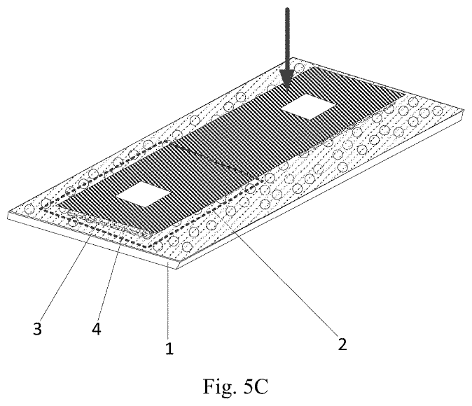

The first step is to form the anodes 3 and the organic functional layers 4 on the base substrate 1 as illustrated in FIG. 5A.

The second step is to coat a layer of metal nanometer material on the base substrate 1 after the first step through physical vapor deposition, inkjet printing or high-temperature evaporation and plating as illustrated in FIG. 5B, where the layer including round particles represents the coated layer of metal nanometer material.

The third step is to irradiate (as denoted by the black arrow in FIG. 5C) and sinter the metal nanometer material on the base substrate 1 using FS laser after the second step, where the metal nanometer material is irradiated using the femto laser for one to three seconds, the wavelength of laser emitted by the FS laser can range from 400 nm to 700 nm, the power of the laser can range from 1000 W/cm² to 3000 W/cm², and the energy of the laser can range from 0.29 J/cm² to 0.85 J/cm², as illustrated in FIG. 5C.

The fourth step is to solve the pattern of the remaining cathode layer which is not cured after the third step, in ethyl acetate, acetone, synthetic acid, or another organic solvent to form the cathodes 5 in the grid structure, where orthographic projections of the cathodes 5 onto the base substrate 1 overlap with the opening areas 2, as illustrated in FIG. 3.

The cathodes in the organic light-emitting diode display panel according to the embodiments of the disclosure as illustrated in FIG. 3 can be formed in the first to fourth steps above.

Based upon the same inventive idea, the embodiments of the disclosure further provide an organic light-emitting diode display panel including the organic light-emitting diode display substrate above according to the embodiments of the disclosure. Since the organic light-emitting diode display panel addresses the problem under a similar principle to the organic light-emitting diode display substrate above, reference can be made to the implementation of the display substrate above for the implementation of the organic light-emitting diode display panel, so a repeated description thereof will be omitted here.

Based upon the same inventive idea, the embodiments of the disclosure further provide a display device including the organic light-emitting diode display panel above according to the embodiments of the disclosure. Since the display device addresses the problem under a similar principle to the organic light-emitting diode display panel above, reference can be made to the implementation of the display panel above for an implementation of the display device, so a repeated description thereof will be omitted here.

Optionally, the display device above according to the embodiments of the disclosure can be all-screen display device, or can be a flexible display device, although the embodiments of the disclosure will not be limited thereto.

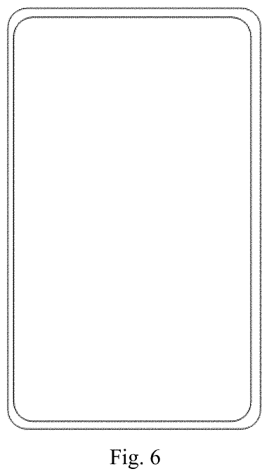

Optionally, the display device above according to the embodiments of the disclosure can be an all-screen mobile phone as illustrated in FIG. 6. of course, the display device above according to the embodiments of the disclosure can alternatively be a tablet computer, a TV set, a monitor, a notebook computer, a digital photo frame, a navigator, or any other product or component with a display function. All the other indispensable components to the display device shall readily occur to those ordinarily skilled in the art, so a repeated description thereof will be omitted here, and the embodiments of the disclosure will not be limited thereto.

In the organic light-emitting diode display substrate, the method for fabricating the same, the organic light-emitting diode display panel, and the display device according to the embodiments of the disclosure, the method includes: forming an integral cathode layer of a metal nanometer material on a base substrate; thermally curing a part of the cathode layer, where the cured part of the cathode layer is patterned in a grid structure; and removing a pattern of the remaining cathode layer which is not cured, to form cathodes in the grid structure. Since high display brightness is required of a top-emitting OLED element with a large size, the resistance of a cathode shall not be too large, so the cathode shall be made with a large thickness, but if the thickness of the cathode is too large, then a light exit ratio of the element may be degraded. Accordingly in the embodiments of the disclosure, the cathodes can be formed in the grid structure in the method above to thereby guarantee a high light exit ratio while guaranteeing the display brightness thereof; and the cathodes are made of the metal nanometer material, and since the metal nanometer material can be thermally cured at a lower temperature, an organic layer will not be destroyed. A flexible OLED display panel with a large size can be fabricated using the cathodes in the grid structure.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. A method for fabricating an organic light-emitting diode display substrate, the method comprising:
forming an integral cathode layer of a metal nanometer material on a base substrate;
thermally curing a part of the cathode layer, wherein the cured part of the cathode layer is patterned in a grid structure; and
removing a pattern of the remaining cathode layer which is not cured, to form cathodes in the grid structure.

2. The method according to claim 1, wherein the forming the integral cathode layer of the metal nanometer material on the base substrate comprises:
coating the metal nanometer material on the base substrate through physical vapor deposition, inkjet printing, or high-temperature evaporation and plating to form the integral cathode layer.

3. The method according to claim 1, wherein the thermally curing a part of the cathode layer comprises:
curing a part of the cathode layer through laser sintering.

4. The method according to claim 1, wherein the removing the pattern of the remaining cathode layer which is not cured, to form the cathodes in the grid structure comprises:
dissolving and removing the pattern of the remaining cathode layer which is not cured, with an organic solvent to form the cathodes in the grid structure.

5. The method according to claim 1, wherein orthographic projections of the cathodes onto the base substrate overlap with opening areas of the base substrate.

6. The method according to claim 3, wherein a wavelength of laser in laser sintering ranges from 400 nm to 700 nm, a power of the laser ranges from 1000 W/cm² to 3000 W/cm², and an energy of the laser ranges from 0.29 J/cm² to 0.85 J/cm².

7. The method according to claim 3, wherein the cathode layer is irradiated with laser in laser sintering for one to three seconds.

8. The method according to claim 4, wherein the organic solvent comprises at least one of ethyl acetate, acetone, or synthetic acid.

9. The method according to claim 1, wherein a melting temperature of the metal nanometer material is below 150° C.

10. An organic light-emitting diode display substrate, comprising a base substrate, and anodes, organic functional layers, and cathodes stacked over the base substrate, wherein the cathodes are in a grid structure, and the cathodes are made of a metal nanometer material.

11. The display substrate according to claim 10, wherein the base substrate comprises a plurality of opening areas, and orthographic projections of the cathodes onto the base substrate overlap with the plurality of opening areas.

12. The display substrate according to claim 10, wherein the base substrate is a flexible base substrate.

13. An organic light-emitting diode display panel, comprising the organic light-emitting diode display substrate according to claim 10.

14. The organic light-emitting diode display panel according to claim 13, wherein the base substrate comprises a plurality of opening areas, and orthographic projections of the cathodes onto the base substrate overlap with the plurality of opening areas.

15. The organic light-emitting diode display panel according to claim 13, wherein the base substrate is a flexible base substrate.

16. A display device, comprising an organic light-emitting diode display panel which comprises an organic light-emitting diode display substrate, wherein the organic light-emitting diode display substrate comprises:
a base substrate, and anodes, organic functional layers, and cathodes stacked over the base substrate, wherein the cathodes are in a grid structure, and the cathodes are made of a metal nanometer material.

17. The display device according to claim 16, wherein the base substrate comprises a plurality of opening areas, and orthographic projections of the cathodes onto the base substrate overlap with the plurality of opening areas.

18. The display device according to claim 16, wherein the base substrate is a flexible base substrate.
